(19) United States
(12) Patent Application Publication
(10) Pub. No.: US 2025/0382453 A1
(43) Pub. Date: Dec. 18, 2025

(54) RESIN COMPOSITION AND ELECTRONIC COMPONENT DEVICE

(71) Applicant: RESONAC CORPORATION, Tokyo (JP)

(72) Inventors: Masashi YAMAURA, Tokyo (JP); Takahiro SAITO, Minato-ku, Tokyo (JP); Ayumi NAKAYAMA, Minato-ku, Tokyo (JP); Yuji NOGUCHI, Minato-ku, Tokyo (JP)

(73) Assignee: RESONAC CORPORATION, Tokyo (JP)

(21) Appl. No.: 18/861,572

(22) PCT Filed: Dec. 5, 2023
(86) PCT No.: PCT/JP2023/043515

§ 371 Date: Oct. 29, 2024

(30) Foreign Application Priority Data
Dec. 8, 2022 (JP) 2022-196516

(51) Int. Cl. C08L 63/00; C08K 3/36; C08K 7/18

(52) U.S. Cl. CPC C08L 63/00; C08K 3/36; C08K 7/18; C08K 2201/005; C08K 2201/006; C08K 2201/014; C08L 2203/206

(57) ABSTRACT

Provided is a resin composition containing a resin component, inorganic particles, and a compound containing an oxyalkylene structure, wherein the maximum particle diameter of the inorganic particles is 5 μm or less.

### TECHNICAL FIELD

The present disclosure relates to a resin composition and an electronic component device.

### RELATED ART

Electronic component devices, in which elements such as semiconductor chips are sealed with an insulating material called a sealing material around the elements or between the elements and the substrate, are used in various electronic devices. As a sealing material, a resin composition including a thermosetting resin such as epoxy resin and inorganic particles such as silica is widely used.

In recent years, with the miniaturization and high performance of electronic devices, electronic component devices have become more refined and highly integrated. As a result, the gap in electronic component devices has become narrower, and in some cases, conventional sealing materials cannot provide sufficient sealing effect.

As a countermeasure to the narrowing gap in electronic component devices, for example, Patent Document 1 describes controlling the particle size of inorganic particles included in the sealing material.
[Patent Document 1] Japanese Patent Application Laid-Open (JP-A) No. 2021-147453.

### SUMMARY

### Technical Problem

When the particle size of inorganic particles included in the sealing material is reduced, it becomes possible to fill the sealing material into narrowed gap spaces. However, there is a problem that the interaction between inorganic particles becomes more likely to cause aggregation, making it difficult for the inorganic particles to disperse well in the resin composition.

In view of such circumstances, the present disclosure aims to provide a resin composition that excels in dispersibility of inorganic particles even when the particle size of the inorganic particles is small, and an electronic component device using this resin composition.

### Solution to Problem

The means for solving the above problem include the following embodiments.
<1> A resin composition, containing a resin component, inorganic particles, and a compound containing an oxyalkylene structure, wherein a maximum particle diameter of the inorganic particles is 5 μm or less.
<2> The resin composition according to <1>, wherein the resin component contains an epoxy resin.
3> The resin composition according to <1> or <2>, wherein a compound containing the oxyalkylene structure contains a silicone compound.
<4> The resin composition according to any one of <1> to <3>, for use as a sealing material for an electronic component device.
<5> An electronic component device, comprising: an element sealed with a resin composition according to any one of <1> to <4>.

### Effects of Invention

According to the present disclosure, a resin composition with excellent dispersibility of inorganic particles even when the particle size of the inorganic particles is small, and an electronic component device using this resin composition are provided.

### DESCRIPTION OF EMBODIMENTS

The following describes in detail the embodiments for implementing the present invention. However, the present invention is not limited to the following embodiments. In the following embodiments, the components (including elements, steps, etc.) are not essential unless specifically stated. The same applies to numerical values and their ranges, which do not limit the present invention.

In the present disclosure, the term “step” includes not only steps independent from other steps, but also steps that may not be clearly distinguishable from other steps, as long as the purpose of the step is achieved.

In the present disclosure, a numerical range indicated using “˜” includes the values before and after “˜” as the minimum and maximum values, respectively.

In the numerical ranges described stepwise in the present disclosure, an upper limit or lower limit value described in one numerical range may be replaced with an upper limit or lower limit value of another stepwise described numerical range. Further, in the numerical ranges described in the present disclosure, the upper limit or lower limit value of the numerical range may be replaced with a value shown in the examples.

In the present disclosure, each component may include multiple types of corresponding substances. In the case where multiple types of substances corresponding to each component exist in the composition, the content ratio or content amount of each component means the total content ratio or content amount of the multiple types of substances present in the composition, unless otherwise specified.

In the present disclosure, particles corresponding to each component may include multiple types. In the case where multiple types of particles corresponding to each component exist in the composition, the particle diameter of each component means the value for the mixture of the multiple types of particles present in the composition, unless otherwise specified.

In the present disclosure, the terms solid, solid state, liquid, and liquid state refer to the properties under normal temperature and pressure (for example, 25° C., under atmospheric pressure), unless otherwise specified.

### <Resin Composition>

The resin composition of the present disclosure is a resin composition that contains a resin component, inorganic particles, and a compound containing an oxyalkylene structure (hereinafter also referred to as an oxyalkylene-containing compound), wherein a maximum particle diameter of the inorganic particles is 5 μm or less.

The resin composition with the above structure excels in dispersion stability of inorganic particles even when the particle size of the inorganic particles is small.

The reason for this may be, for example, that the oxyalkylene-containing compound contained in the resin composition functions to compatibilize the interface between the inorganic particles and the surrounding resin component, thereby suppressing the aggregation of inorganic particles due to their interaction.

The type of resin component included in the resin composition is not particularly limited and may be selected according to the application of the resin composition, etc.

For example, in the case of using the resin composition as a sealing material for an electronic component device, the resin composition may include a thermosetting resin and a curing agent as the resin component.

### (Thermosetting Resin)

The type of thermosetting resin contained in the resin composition is not particularly limited. Specifically, as the thermosetting resin, epoxy resin, phenol resin, urea resin, melamine resin, urethane resin, silicone resin (excluding those corresponding to oxyalkylene-containing compounds), unsaturated polyester resin, etc. may be mentioned. In the present disclosure, those exhibiting both thermoplastic and thermosetting properties, such as acrylic resins containing epoxy groups, are included in “thermosetting resin”. The thermosetting resin may be solid or liquid, and is preferably solid. The thermosetting resin may be used alone or in combination of two or more types.

The thermosetting resin preferably includes epoxy resin. Specifically, as the epoxy resin, the following may be mentioned: novolac-type epoxy resins (phenol novolac-type epoxy resin, o-cresol novolac-type epoxy resin, etc.) obtained by epoxidizing novolac resins produced by condensation or co-condensation under acidic catalyst of at least one phenolic compound selected from the group consisting of phenol compounds such as phenol, cresol, xylenol, resorcinol, catechol, bisphenol A, bisphenol F, etc., and naphthol compounds such as α-naphthol, β-naphthol, dihydroxynaphthalene, etc., with aliphatic aldehyde compounds such as formaldehyde, acetaldehyde, propionaldehyde, etc.; triphenylmethane-type epoxy resins obtained by epoxidizing triphenylmethane-type phenol resins produced by condensation or co-condensation under acidic catalyst of the aforementioned phenolic compounds with aromatic aldehyde compounds such as benzaldehyde, salicylaldehyde, etc.; copolymer-type epoxy resins obtained by epoxidizing novolac resins produced by co-condensation under acidic catalyst of the aforementioned phenol compounds and naphthol compounds with aldehyde compounds; diphenylmethane-type epoxy resins which are diglycidyl ethers of bisphenol A, bisphenol F, etc.; biphenyl-type epoxy resins which are diglycidyl ethers of alkyl-substituted or unsubstituted biphenols; stilbene-type epoxy resins which are diglycidyl ethers of stilbene-based phenol compounds; sulfur atom-containing type epoxy resins which are diglycidyl ethers of bisphenol S, etc.; epoxy resins which are glycidyl ethers of alcohols such as butanediol, polyethylene glycol, polypropylene glycol, etc.; glycidyl ester-type epoxy resins which are glycidyl esters of polyvalent carboxylic acid compounds such as phthalic acid, isophthalic acid, tetrahydrophthalic acid, etc.; glycidylamine-type epoxy resins in which active hydrogens bonded to nitrogen atoms of aniline, diaminodiphenylmethane, isocyanuric acid, etc. are substituted with glycidyl groups; dicyclopentadiene-type epoxy resins obtained by epoxidizing co-condensation resins of dicyclopentadiene and phenol compounds; alicyclic epoxy resins such as vinylcyclohexene diepoxide, 3,4-epoxycyclohexylmethyl-3,4-epoxycyclohexanecarboxylate, 2-(3,4-epoxy)cyclohexyl-5,5-spiro(3,4-epoxy)cyclohexane-m-dioxane, etc., in which olefin bonds in the molecule are epoxidized; paraxylylene-modified epoxy resins which are glycidyl ethers of paraxylylene-modified phenol resins; metaxylylene-modified epoxy resins which are glycidyl ethers of metaxylylene-modified phenol resins; terpene-modified epoxy resins which are glycidyl ethers of terpene-modified phenol resins; dicyclopentadiene-modified epoxy resins which are glycidyl ethers of dicyclopentadiene-modified phenol resins; cyclopentadiene-modified epoxy resins which are glycidyl ethers of cyclopentadiene-modified phenol resins; polycyclic aromatic ring-modified epoxy resins which are glycidyl ethers of polycyclic aromatic ring-modified phenol resins; naphthalene-type epoxy resins which are glycidyl ethers of naphthalene ring-containing phenol resins; halogenated phenol novolac-type epoxy resins; hydroquinone-type epoxy resins; trimethylolpropane-type epoxy resins; linear aliphatic epoxy resins obtained by oxidizing olefin bonds with peracids such as peracetic acid; aralkyl-type epoxy resins obtained by epoxidizing aralkyl-type phenol resins such as phenol aralkyl resins, naphthol aralkyl resins, etc. The epoxy resin may be used alone or in combination of two or more types.

In the case where the thermosetting resin is an epoxy resin, the epoxy equivalent (molecular weight/number of epoxy groups) of the epoxy resin is not particularly limited. From the perspective of balancing various characteristics such as moldability, reflow resistance, and electrical reliability, it is preferably 100 g/eq to 1000 g/eq, and more preferably 150 g/eq to 500 g/eq. The epoxy equivalent of the epoxy resin is defined as the value measured according to the method conforming to JIS K 7236:2009.

In the case where the thermosetting resin is solid at 25° C., the melting point or softening point of the thermosetting resin is not particularly limited. From the perspective of anti-blocking properties, the melting point or softening point of the thermosetting resin is preferably 40° C. or more, and more preferably 50° C. or more. From the perspective of suppressing the increase in viscosity of the resin composition due to kneading, the melting point or softening point of the thermosetting resin is preferably 150° C. or less, more preferably 140° C. or less, and even more preferably 130° C. or less.

The content ratio of the thermosetting resin is preferably 0.5 mass % to 50 mass %, more preferably 2 mass % to 30 mass %, and even more preferably 2 mass % to 20 mass % with respect to the total mass of the resin composition, from the perspective of strength, fluidity, heat resistance, and moldability.

### (Curing Agent)

The resin composition may include a curing agent used in combination with the thermosetting resin. As curing agents used in combination with epoxy resin, phenol curing agents, amine curing agents, acid anhydride curing agents, polymercaptan curing agents, polyaminoamide curing agents, isocyanate curing agents, blocked isocyanate curing agents, etc. may be mentioned. The curing agent may be used alone or in combination of two or more types. From the perspective of improving heat resistance, the curing agent is preferably a phenol curing agent (a curing agent containing phenolic hydroxyl groups as functional groups that react with epoxy groups). The curing agent may be solid or liquid under normal temperature and pressure (for example, at 25° C., under atmospheric pressure), and is preferably solid.

Specifically, as the phenol curing agent, the following may be mentioned: multivalent phenol compounds such as resorcinol, catechol, bisphenol A, bisphenol F, substituted or unsubstituted biphenols, etc.; novolac-type phenol resins obtained by condensation or co-condensation under acidic catalyst of at least one phenolic compound selected from the group consisting of phenol compounds such as phenol, cresol, xylenol, resorcinol, catechol, bisphenol A, bisphenol F, phenylphenol, aminophenol, and naphthol compounds such as α-naphthol, β-naphthol, dihydroxynaphthalene, with aldehyde compounds such as formaldehyde, acetaldehyde, propionaldehyde, benzaldehyde, salicylaldehyde; aralkyl-type phenol resins such as phenol aralkyl resins and naphthol aralkyl resins synthesized from the aforementioned phenolic compounds and compounds such as dimethoxy paraxylene, bis(methoxymethyl) biphenyl; paraxylylene and/or metaxylylene modified phenol resins; melamine-modified phenol resins; terpene-modified phenol resins; dicyclopentadiene-type phenol resins and dicyclopentadiene-type naphthol resins synthesized by copolymerization of the aforementioned phenolic compounds with dicyclopentadiene; cyclopentadiene-modified phenol resins; polycyclic aromatic ring-modified phenol resins; biphenyl-type phenol resins; triphenylmethane-type phenol resins obtained by condensation or co-condensation under acidic catalyst of the aforementioned phenolic compounds with aromatic aldehyde compounds such as benzaldehyde, salicylaldehyde; and phenol resins obtained by copolymerization of two or more of these. The phenol curing agent may be used alone or in combination of two or more types.

The functional group equivalent of the curing agent (hydroxyl group equivalent in the case of phenol curing agents, active hydrogen equivalent in the case of amine curing agents) is not particularly limited. From the perspective of balancing various characteristics such as moldability, reflow resistance, and electrical reliability, the functional group equivalent of the curing agent is preferably 70 g/eq to 1000 g/eq, and more preferably 80 g/eq to 500 g/eq.

In the case of phenol curing agents, the hydroxyl group equivalent refers to the value calculated based on the hydroxyl value measured in accordance with JIS K 0070:1992. Further, in the case of amine curing agents, the active hydrogen equivalent refers to the value calculated based on the amine value measured in accordance with JIS K 7237:1995.

In the case where the curing agent is a solid, its softening point or melting point is not particularly limited. The softening point or melting point of the curing agent is preferably 40° C. to 180° C. from the perspective of moldability and reflow resistance when the resin composition is used as a sealing material, and more preferably 50° C. to 130° C. from the perspective of handling during the manufacturing of the resin composition.

The melting point or softening point of the curing agent is defined as the value measured in the same manner as the melting point or softening point of the epoxy resin.

The equivalent ratio of the thermosetting resin to the curing agent, that is, the ratio of the number of functional groups in the curing agent to the number of functional groups in the thermosetting resin (number of functional groups in the curing agent/number of functional groups in the thermosetting resin), is not particularly limited. From the perspective of minimizing the unreacted portions of each component, the equivalent ratio of the thermosetting resin to the curing agent is preferably set in the range of 0.5 to 2.0, and more preferably set in the range of 0.6 to 1.3. From the perspective of moldability, the equivalent ratio of the thermosetting resin to the curing agent is further preferably set in the range of 0.8 to 1.2.

### (Inorganic Particles)

The material of the inorganic particles included in the resin composition is not particularly limited. Specifically, as the material of the inorganic particles, inorganic materials such as silica including fused silica and crystalline silica, glass, alumina, calcium carbonate, zirconium silicate, calcium silicate, silicon nitride, aluminum nitride, boron nitride, magnesium oxide, silicon carbide, beryllia, zirconia, zircon, forsterite, steatite, spinel, mullite, titania, talc, clay, and mica may be mentioned. Inorganic particles having flame retardant effects may also be used. As inorganic particles having flame retardant effects, aluminum hydroxide, magnesium hydroxide, composite metal hydroxides such as composite hydroxides of magnesium and zinc, zinc borate, and the like may be mentioned. Among the inorganic particles, silica such as fused silica is preferable from the perspective of reducing the linear expansion coefficient, and alumina is preferable from the perspective of high thermal conductivity.

The inorganic particles contained in the resin composition may be of a single type or two or more types.

In the present disclosure, the maximum particle diameter of the inorganic particles contained in the resin composition is 5.0 μm or less. The maximum particle diameter of the inorganic particles included in the resin composition may be less than 5.0 μm, 4.5 μm or less, 4.0 μm or less, or 3.5 μm or less.

The volume average particle diameter of the inorganic particles is not particularly limited. From the perspective of accommodating the narrow gap of the electronic component device, the volume average particle diameter of the inorganic particles is preferably 4.0 μm or less, more preferably 3.5 μm or less, and further preferably 3.0 μm or less.

From the perspective of suppressing the aggregation of inorganic particles, the volume average particle diameter of the inorganic particles is preferably 0.1 μm or more, more preferably 0.2 μm or more, and further preferably 0.3 μm or more.

The volume average particle diameter of the inorganic particles may be measured as the particle diameter (D50) at which the cumulative volume from the small diameter side reaches 50% in the volume-based particle size distribution measured by a laser diffraction particle size distribution analyzer.

The specific surface area of the inorganic particles measured by the BET method is not particularly limited. From the perspective of accommodating the narrow gap of the electronic component device, the specific surface area of the inorganic particles measured by the BET method is preferably 0.1 m²/g or more, more preferably 0.5 m²/g or more, and further preferably 1.0 m²/g or more.

From the perspective of suppressing the aggregation of inorganic particles, the specific surface area of the inorganic particles measured by the BET method is preferably 50 m²/g or less, more preferably 20 m²/g or less, and further preferably 10 m²/g or less.

The specific surface area of the inorganic particles measured by the BET method may be determined from the nitrogen adsorption capacity of the inorganic particles in accordance with JIS Z 8830:2013.

The specific surface area of the inorganic particles measured by the image analysis method is not particularly limited. From the perspective of accommodating the narrow gap of the electronic component device, the specific surface area of the inorganic particles measured by the image analysis method is preferably 0.1 m²/g or more, more preferably 0.5 m²/g or more, and further preferably 1.0 m²/g or more.

From the perspective of suppressing the aggregation of inorganic particles, the specific surface area of the inorganic particles measured by the image analysis method is preferably 50 m²/g or less, more preferably 20 m²/g or less, and further preferably 10 m²/g or less.

The specific surface area of the inorganic particles measured by the image analysis method may be calculated by obtaining an image of the inorganic particles using an electron microscope or the like, and assuming that the particles in the obtained image are spherical.

The shape of the inorganic particles is not particularly limited, but from the perspective of filling properties and mold wear resistance, a spherical shape is preferred.

The content ratio of the inorganic particles is not particularly limited. From the perspective of further improving the characteristics such as the thermal expansion coefficient, thermal conductivity, and elastic modulus of the cured product of the resin composition, the content ratio of the inorganic particles is preferably 30 volume % or more of the resin composition as a whole, more preferably 40 volume % or more, further preferably 50 volume % or more, particularly preferably 60 volume % or more, and most preferably 70 volume % or more. From the perspective of improving the fluidity of the resin composition and reducing the viscosity, the content ratio of the inorganic particles is preferably 99 volume % or less of the resin composition as a whole, more preferably 98 volume % or less, and further preferably 97 volume % or less. Further, for example, in the case of using the resin composition for compression molding, the content ratio of the inorganic particles may be 70 volume % to 99 volume % of the resin composition as a whole, or may be 80 volume % to 99 volume %, or may be 83 volume % to 99 volume %, or may be 85 volume % to 99 volume %.

The content ratio of the inorganic particles in the cured product of the resin composition may be measured as follows. First, the total mass of the cured product is measured, and the cured product is calcined at 400° C. for 2 hours, then at 700° C. for 3 hours to evaporate the resin components and other components, and the mass of the remaining inorganic particles is measured.

The volume is calculated from the obtained masses and their respective specific gravities, and the ratio of the volume of the inorganic particles to the total volume of the cured product is obtained to determine the content ratio of the inorganic particles.

### (Oxyalkylene-Containing Compound)

In the present disclosure, an oxyalkylene-containing compound refers to a compound that includes an oxyalkylene structure in the molecule thereof. The oxyalkylene structure refers to a molecular structure represented by —[O—CmH₂ₘ]ₙ—. In the formula, n may be 1 or a number of 2 or more (i.e., polyalkylene oxide). In the formula, m may be 2 (ethylene), 3 (propylene), or a number greater than that, and may be a combination of structural units with different m values. From the perspective of dispersibility of the inorganic particles, m is preferably 2 or 3.

The type of oxyalkylene-containing compound contained in the resin composition is not particularly limited. For example, silicone resins such as silicone compounds, acrylic resins, ester resins, fluorine resins, etc. may be mentioned. From the perspective of obtaining an effect as a stress relaxing agent for the resin composition, a silicone compound is preferred as the oxyalkylene-containing compound. In the present disclosure, a silicone compound refers to a compound having a main chain consisting of siloxane bonds.

The resin composition may include only one type of oxyalkylene-containing compound or may include two or more types.

The oxyalkylene-containing compound may include functional groups other than the oxyalkylene structure. By including functional groups other than the oxyalkylene structure in the oxyalkylene-containing compound, for example, the functional group may react with the resin component or inorganic particles in the resin composition to suppress the leaching of components from the cured product. Specifically, as functional groups other than the oxyalkylene structure, epoxy groups, amino groups, mercapto groups, vinyl groups, acrylic groups, methacrylic groups, isocyanate groups, acid anhydride groups, aralkyl groups, etc. may be mentioned. Among these, epoxy groups and amino groups are preferred, with epoxy groups being more preferred.

The oxyalkylene-containing compound may include only one type of functional group other than the oxyalkylene structure or may include two or more types.

In a certain embodiment, the oxyalkylene-containing compound may be a silicone compound containing an oxyalkylene structure in its side chain, or it may be a silicone compound containing an oxyalkylene structure in its side chain and containing a functional group other than the oxyalkylene structure in at least one of the side chain or the main chain terminal.

The molecular weight of the oxyalkylene-containing compound is not particularly limited. For example, it may be selected from a range of 200 to 10000. The oxyalkylene-containing compound may be in a liquid or solid state before mixing with other raw materials.

From the perspective of ease of mixing with the thermosetting resin and inorganic particles, it is preferable to be in a liquid state.

The content ratio of the oxyalkylene-containing compound in the resin composition is not particularly limited. From the perspective of dispersibility of inorganic particles, the content ratio of the oxyalkylene-containing compound is preferably 0.2 mass % or more, more preferably 0.7 mass % or more, and even more preferably 1.0 mass % or more, with respect to the total mass of the resin composition.

From the perspective of suppressing strength reduction during curing of the resin composition, the content ratio of the oxyalkylene-containing compound is preferably 5.0 mass % or less, more preferably 3.0 mass % or less, and even more preferably 2.0 mass % or less, with respect to the total mass of the resin composition.

The content ratio of the oxyalkylene-containing compound in the resin composition is not particularly limited. From the perspective of dispersibility of inorganic particles, the content ratio of the oxyalkylene-containing compound is preferably 0.2 parts by mass or more, more preferably 0.7 parts by mass or more, and even more preferably 1.0 parts by mass or more, with respect to 100 parts by mass of the inorganic particles.

From the perspective of suppressing strength reduction during curing of the resin composition, the content ratio of the oxyalkylene-containing compound is preferably 5.0 parts by mass or less, more preferably 3.0 parts by mass or less, and even more preferably 2.0 parts by mass or less, with respect to 100 parts by mass of the inorganic particles.

### (Curing Accelerator)

The resin composition may include a curing accelerator. Specifically, as the curing accelerator, the following may be mentioned: cyclic amidine compounds such as 1,5-diazabicyclo[4.3.0]non-5-ene (DBN), 1,8-diazabicyclo[5.4.0]undec-7-ene (DBU) and other diazabicycloalkenes, 2-methylimidazole, 2-phenylimidazole, 2-phenyl-4-methylimidazole, 2-heptadecylimidazole; derivatives of the aforementioned cyclic amidine compounds; phenol novolac salts of the aforementioned cyclic amidine compounds or their derivatives; compounds having intramolecular polarization formed by adding compounds with π-bonds such as quinone compounds like maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, and diazophenylmethane to these compounds; cyclic amidinium compounds such as tetraphenylborate salt of DBU, tetraphenylborate salt of DBN, 2-ethyl-4-methylimidazole, N-methylmorpholine; tertiary amine compounds such as pyridine, triethylamine, triethylenediamine, benzyldimethylamine, triethanolamine, dimethylaminoethanol, tris(dimethylaminomethyl) phenol; derivatives of the aforementioned tertiary amine compounds; ammonium salt compounds such as tetra-n-butylammonium acetate, tetra-n-butylammonium phosphate, tetraethylammonium acetate, tetra-n-hexylammonium benzoate, tetrapropylammonium hydroxide; organic phosphines such as primary phosphines like ethylphosphine and phenylphosphine, secondary phosphines like dimethylphosphine and diphenylphosphine, tertiary phosphines like triphenylphosphine, diphenyl(p-tolyl)phosphine, tris(alkylphenyl)phosphine, tris(alkoxyphenyl)phosphine, tris(alkyl·alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylalylphosphine, alkyldiarylphosphine, trinaphthylphosphine, tris(benzyl)phosphine; phosphine compounds such as complexes of the aforementioned organic phosphines with organic boron compounds; compounds having intramolecular polarization formed by adding compounds with π-bonds such as maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, anthraquinone, and diazophenylmethane to the aforementioned organic phosphines or phosphine compounds; compounds having intramolecular polarization obtained through a dehydrohalogenation process after reacting the aforementioned organic phosphines or phosphine compounds with halogenated phenol compounds such as 4-bromophenol, 3-bromophenol, 2-bromophenol, 4-chlorophenol, 3-chlorophenol, 2-chlorophenol, 4-iodophenol, 3-iodophenol, 2-iodophenol, 4-bromo-2-methylphenol, 4-bromo-3-methylphenol, 4-bromo-2,6-dimethylphenol, 4-bromo-3,5-dimethylphenol, 4-bromo-2,6-di-tert-butylphenol, 4-chloro-1-naphthol, 1-bromo-2-naphthol, 6-bromo-2-naphthol, 4-bromo-4′-hydroxybiphenyl; tetrasubstituted phosphonium compounds such as tetraphenylphosphonium, tetraphenylborate salts of tetrasubstituted phosphonium like tetraphenylphosphonium tetra-p-tolylborate, salts of tetrasubstituted phosphonium with phenol compounds; phosphobetaine compounds; adducts of phosphonium compounds with silane compounds; and others. The curing accelerator may be used alone or in combination of two or more types.

In the case of using epoxy resin as the thermosetting resin, particularly suitable curing accelerators include triphenylphosphine, adducts of triphenylphosphine with quinone compounds, and the like.

The content ratio of the curing accelerator is preferably 0.1 parts by mass to 30 parts by mass, and more preferably 1 part by mass to 15 parts by mass, with respect to 100 parts by mass of the resin component. In the case where the amount of the curing accelerator is 0.1 parts by mass or more with respect to 100 parts by mass of the resin component, there is a tendency for good curing to occur in a short time. In the case where the amount of the curing accelerator is 30 parts by mass or less with respect to 100 parts by mass of the resin component, there is a tendency for the curing speed to not be too fast and for a good molded product to be obtained.

### (Additives)

The resin composition may include, in addition to the above-mentioned components, various additives such as coupling agents, ion exchangers, release agents, flame retardants, colorants, stress relaxing agents, and the like. The resin composition may also include various additives commonly used in this technical field as needed, in addition to the additives exemplified below.

### (Coupling Agent)

The resin composition may include a coupling agent to enhance the adhesion between the resin component and the inorganic particles. As coupling agents, known coupling agents such as silane-based compounds, titanium-based compounds, aluminum chelate compounds, aluminum/zirconium-based compounds, and the like may be mentioned.

As silane-based compounds, 3-glycidoxypropyltrimethoxysilane, 3-glycidoxypropyltriethoxysilane, 3-glycidoxypropylmethyldiethoxysilane, 3-glycidoxypropylmethyldimethoxysilane, 2-(3,4-epoxycyclohexyl)ethyltrimethoxysilane, 3-aminopropyltriethoxysilane, 3-(2-aminoethyl)aminopropyltrimethoxysilane, 3-(2-aminoethyl)aminopropyltriethoxysilane, 3-aminopropyltrimethoxysilane, N-phenyl-3-aminopropyltrimethoxysilane, 3-mercaptopropyltrimethoxysilane, 3-mercaptopropyltriethoxysilane, 3-ureidopropyltriethoxysilane, octenyltrimethoxysilane, glycidoxyoctyltrimethoxysilane, and methacryloxyoctyltrimethoxysilane may be mentioned.

As titanium-based compounds, isopropyl triisostearoyl titanate, isopropyl tris(dioctylpyrophosphate) titanate, isopropyl tri (N-aminoethyl-aminoethyl) titanate, tetraoctyl bis(ditridecylphosphite) titanate, tetra(2,2-diallyloxymethyl-1-butyl) bis(ditridecylphosphite) titanate, bis(dioctylpyrophosphate) oxyacetate titanate, bis(dioctylpyrophosphate) ethylene titanate, isopropyl trioctanoyl titanate, isopropyl dimethacryl isostearoyl titanate, isopropyl tridodecylbenzenesulfonyl titanate, isopropyl isostearoyl diacryl titanate, isopropyl tri (dioctylphosphate) titanate, isopropyl tricumylphenyl titanate, tetraisopropyl bis(dioctylphosphite) titanate, and the like may be mentioned.

In the case where the resin composition contains a coupling agent, the amount of the coupling agent is preferably 0.05 parts by mass to 20 parts by mass, and more preferably 0.1 parts by mass to 15 parts by mass, with respect to 100 parts by mass of the inorganic particles.

### (Ion Exchanger)

The resin composition may include an ion exchanger. Especially, in the case where the resin composition is used as a sealing molding material, it is preferable to include an ion exchanger from the perspective of improving moisture resistance and high-temperature storage characteristics of the electronic component device equipped with the element to be sealed. The ion exchanger is not particularly limited, and conventionally known ones may be used. Specifically, hydrotalcite compounds, and hydrated hydroxides of at least one element selected from the group consisting of magnesium, aluminum, titanium, zirconium, and bismuth may be mentioned. The ion exchanger may be used alone or in combination of two or more types. Among these, hydrotalcite represented by the following general formula (A) is preferable.

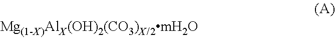

(0<X≤0.5, and m is a positive number)

In the case where the resin composition includes an ion exchanger, there is no particular limitation on its amount as long as it is sufficient to capture ions such as halogen ions. For example, the amount of the ion exchanger is preferably 0.1 parts by mass to 30 parts by mass, and more preferably 1 part by mass to 10 parts by mass, with respect to 100 parts by mass of the resin component.

### (Release Agent)

The resin composition may include a release agent from the perspective of obtaining good releasability from the mold during molding. The release agent is not particularly limited, and conventionally known ones may be used. Specifically, carnauba wax, montan acid, higher fatty acids such as stearic acid, metal salts of higher fatty acids, ester-based waxes such as montan acid ester, polyolefin-based waxes such as oxidized polyethylene and non-oxidized polyethylene may be mentioned. The release agent may be used alone or in combination of two or more types.

In the case where the resin composition includes a release agent, its amount is preferably 0.01 parts by mass to 10 parts by mass, and more preferably 0.1 parts by mass to 5 parts by mass, with respect to 100 parts by mass of the resin component. When the amount of the release agent is 0.01 parts by mass or more with respect to 100 parts by mass of the resin component, there is a tendency to obtain sufficient releasability. When it is 10 parts by mass or less, there is a tendency to obtain better adhesion and curability.

### (Flame Retardant)

The resin composition may include a flame retardant. The flame retardant is not particularly limited, and conventionally known ones may be used. Specifically, organic or inorganic compounds containing halogen atoms, antimony atoms, nitrogen atoms or phosphorus atoms, metal hydroxides, etc. may be mentioned. The flame retardant may be used alone or in combination of two or more types.

In the case where the resin composition includes a flame retardant, there is no particular limitation on its amount as long as it is sufficient to obtain the desired flame retardant effect. For example, it is preferably 1 part by mass to 30 parts by mass, and more preferably 2 parts by mass to 20 parts by mass, with respect to 100 parts by mass of the resin component.

### (Colorant)

The resin composition may include a colorant. As the colorant, known colorants such as carbon black, organic dyes, organic pigments, titanium oxide, red lead, and bengala may be mentioned. The content of the colorant may be appropriately selected according to the purpose, etc. The colorant may be used alone or in combination of two or more types.

In the case where the resin composition includes a colorant, there is no particular limitation on its amount as long as it is sufficient to obtain the desired coloring effect. For example, the amount of the colorant is preferably 1 part by mass to 30 parts by mass, and more preferably 2 parts by mass to 20 parts by mass, with respect to 100 parts by mass of the resin component.

### (Stress Relaxing Agent)

The resin composition may include a stress relaxing agent. By including a stress relaxing agent, it is possible to reduce the occurrence of warpage deformation and package cracking when the resin composition is used as a sealing material. As the stress relaxing agent, known stress relaxing agents (flexibilizers) generally used may be mentioned. Specifically, thermoplastic elastomers such as silicone-based, styrene-based, olefin-based, urethane-based, polyester-based, polyether-based, polyamide-based, polybutadiene-based, etc., rubber particles such as NR (natural rubber), NBR (acrylonitrile-butadiene rubber), acrylic rubber, urethane rubber, silicone powder, etc., and rubber particles having a core-shell structure such as methyl methacrylate-styrene-butadiene copolymer (MBS), methyl methacrylate-silicone copolymer, methyl methacrylate-butyl acrylate copolymer, etc. may be mentioned. The stress relaxing agent may be used alone or in combination of two or more types.

As the oxyalkylene-containing compound included in the resin composition, a compound that also functions as a stress relaxing agent (such as a silicone compound) may be used.

In the case where the resin composition includes a stress relaxing agent, there is no particular limitation on its amount (excluding the amount of the oxyalkylene-containing compound) as long as it is sufficient to obtain the desired stress relaxing effect. For example, the amount of the stress relaxing agent is preferably 1 part by mass to 30 parts by mass, and more preferably 2 parts by mass to 20 parts by mass, with respect to 100 parts by mass of the resin component.

The resin composition may be solid or liquid under normal temperature and pressure (for example, at 25° C., under atmospheric pressure), and it is preferably solid. In the case where the resin composition is solid, there is no particular limitation on its shape, and powder, granular, tablet, etc. may be mentioned.

The resin composition manufactured by the method of the present disclosure may be used for various applications. As a suitable application of the resin composition, a sealing material for electronic component devices may be mentioned.

### <Electronic Component Device>

The electronic component device of the present disclosure is an electronic component device including an element sealed with the resin composition of the present disclosure described above. Specifically, as the electronic component device, one that includes a support member, an element mounted on the support member, and a sealing material sealing the surroundings of the element may be mentioned.

As the support member, a lead frame, a wired tape carrier, a wiring board, glass, a silicon wafer, an organic substrate, etc. may be mentioned.

As the element, active elements such as semiconductor chips, transistors, diodes, thyristors, etc., and passive elements such as capacitors, resistors, coils, etc. may be mentioned.

The method of sealing the electronic component device using the resin composition is not particularly limited and may be selected from known techniques. For example, low-pressure transfer molding method, injection molding method, compression molding method, etc. may be mentioned.

### <Manufacturing Method of the Resin Composition>

The method of manufacturing the resin composition is not particularly limited and may be implemented using known techniques.

From the perspective of workability when mixing the inorganic particles and other raw materials, the resin composition may be manufactured by preparing granules including the inorganic particles and resin components, and mixing these granules with other raw materials.

In the present disclosure, “granules including inorganic particles and resin components” refers to a material containing at least inorganic particles and resin components that has been granulated.

The resin component used for preparing the granules may be the resin component as a whole or a part of the resin component included in the resin composition.

For example, in the case where the resin composition includes a thermosetting resin and a curing agent as resin components, granules including inorganic particles and the thermosetting resin, and granules including inorganic particles and the curing agent may be prepared separately, or as granules including inorganic particles and resin components, only either granules including inorganic particles and the thermosetting resin or granules including inorganic particles and the curing agent may be prepared.

The granules including inorganic particles and resin components may also include components other than the inorganic particles and resin components. For example, the granules may include an oxyalkylene-containing compound.

From the perspective of suppressing the aggregation of inorganic particles, it is preferable that the resin component used for preparing the granules has an opposite charge to that of the inorganic particles. For example, in the case where the surface of the inorganic particles is positively charged, it is preferable to use a resin component having an anionic functional group such as a phenolic hydroxyl group, and in the case where the surface of the inorganic particles is negatively charged, it is preferable to use a resin component having a cationic functional group such as an amino group.

The particle diameter of the granules is not particularly limited and may be selected in consideration of workability when mixing with other materials.

The particle diameter of the granules may be selected from a range of 10 μm to 10000 μm, preferably in the range of 100 μm to 5000 μm, and more preferably in the range of 500 μm to 3000 μm.

The particle shape of the granules is not particularly limited and may be spherical, columnar, flake-like, needle-like, etc.

The method of preparing granules including inorganic particles and resin components, and mixing these granules with other raw materials is particularly suitable for manufacturing a resin composition using a kneading extruder. In the case of feeding inorganic particles that are not in a granulated state from the feeder of the kneading extruder, if the particle diameter of the inorganic particles is too small, it tends to cause a decrease in kneading efficiency and poor kneading. In the above method, the inorganic particles are fed into the kneading extruder after being preliminarily granulated. Thus, even in the case where the particle diameter of the inorganic particles is extremely small (i.e., the maximum particle diameter is 5 μm or less), a uniform resin composition may be efficiently manufactured using a kneading extruder.

### EXAMPLES

The following examples specifically describe the above-mentioned embodiments, but the present disclosure is not limited to these examples.

### (1) Preparation of Granules

The materials (parts by mass) shown in Table 1 were fed into a 3 L separable flask, a stirring blade was inserted, and the mixture was stirred at 200 rpm (rotations/minute) for 2 hours to obtain a varnish-like mixture.

Subsequently, vacuum drying was performed at 140° C. for 2 hours to remove the solvent until the residual solvent content of the mixture became less than 1 mass % to obtain a solid. The obtained solid was pulverized to produce granules (MB) with a particle diameter of 1000 μm.

The obtained granules (2.5 g) and acetone (20 g) were mixed, and the resin component in the granules was dissolved in acetone. Subsequently, the mixture was filtered using a filter with a mesh size of 20 μm, and the filtered material was washed with acetone and dried to obtain a residue. The residue rate was calculated using the following equation. The results are shown in Table 1.

$$Residue rate ( \% ) = ( Mass of residue A / Mass of granules B ) \times 100$$

### (2) Preparation of Resin Composition

The materials (parts by mass) shown in Table 1 were fed into a kneading extruder to obtain a kneaded mixture. The obtained kneaded mixture was pulverized to obtain a resin composition with a particle diameter of 1000 μm.

The obtained resin composition (2.5 g) and acetone (20 g) were mixed, and the resin component in the resin composition was dissolved in acetone. Subsequently, the mixture was filtered using a filter with a mesh size of 20 μm, and the filtered material was washed with acetone and dried to obtain a residue. The residue rate was calculated using the following equation. The results are shown in Table 1.

$$Residue rate ( \% ) = ( Mass of residue A / Mass of resin composition B ) \times 100$$

### (3) Evaluation of Physical Properties of Resin Composition

Using the resin composition, spiral flow (SF), gel time (GT), storage modulus, glass transition temperature (Tg), and molding shrinkage rate were measured according to the following methods. The results are shown in Table 2.

### (Spiral Flow)

The spiral flow was measured as the flow distance (cm) when the resin composition was molded using a mold for spiral flow measurement in accordance with EMMI-1-66, under the conditions of a mold temperature of 175° C., molding pressure of 6.9 MPa, and curing time of 120 seconds. The spiral flow of the resin composition is preferably 80 cm or more, more preferably 90 cm or more, and even more preferably 100 cm or more. The upper limit value of the spiral flow is not particularly limited, and for example, 200 cm may be mentioned.

### (Gel Time)

A sample of 0.5 g of the resin composition was placed on a hot plate heated to 175° C., and spread into a circular shape of 2.0 cm to 2.5 cm using a jig at a rotation speed of 20 to 25 rotations per minute. The time (seconds) from when the sample was placed on the hot plate until the sample lost its viscosity, became gel-like, and started to peel off from the hot plate was measured as the gel time.

The gel time of the resin composition at 175° C. is preferably 30 seconds to 90 seconds, and more preferably 40 seconds to 60 seconds.

### (Storage Modulus)

A sheet with a thickness of 0.8 mm was molded using the resin composition under the conditions of a mold temperature of 175° C., molding pressure of 7 MPa, and curing time of 90 seconds. A plate of 4 mm×25 mm was cut out from the sheet to prepare a test piece. The test piece was set in a solid viscoelasticity measuring device (for example, model RSA-G2 manufactured by TA Instruments), and dynamic viscoelasticity measurement was performed by the three-point bending mode. The measurement conditions were as follows: temperature range: 10° C. to 40° C., heating rate: 5° C./min, frequency: 10 Hz, strain: 0.2%, atmosphere: in nitrogen gas flow. The storage modulus E′ (GPa) at 25° C. is shown in Table 2.

### (Glass Transition Temperature)

The linear expansion coefficient of the cured product of the resin composition was measured in the range of 40° C. to 240° C., and the temperature at the intersection point of the tangent line in the range of 40° C. to 80° C. and the tangent line in the range of 200° C. to 240° C. obtained from the measurement was defined as the glass transition temperature (° C.) of the cured product.

The linear expansion coefficient of the cured product was measured by thermal mechanical analysis (TMA) based on JIS K 7197:2012. Specifically, the linear expansion coefficient was defined as the slope of the tangent line in the range of 40° C. to 240° C. when the strain of the cured product was plotted against temperature. The measurement was performed with a test load of 5 g and a heating rate of 5° C./min. A TMA4000SE from Netzsch was used as the thermal mechanical analysis device.

The test piece used for measuring the linear expansion coefficient was prepared by molding the resin composition using a transfer molding machine under the conditions of a mold temperature of 175° C., molding pressure of 6.9 MPa, and curing time of 90 seconds, followed by post-curing under the conditions of 175° C. for 5 hours. The shape of the test piece was a rectangular parallelepiped with dimensions of 4 mm×4 mm×20 mm.

### (Molding Shrinkage Rate)

The resin composition was molded using a transfer molding machine under the conditions of molding temperature of 175° C., molding pressure of 6.9 MPa, and curing time of 120 seconds to obtain a plate-shaped molded product (127 mm in length, 12.7 mm in width, and 6.4 mm in thickness). The molding shrinkage rate (%) was calculated using the following equation based on the length D of the mold cavity measured in advance at 25° C. and the length d of the molded product at room temperature (25° C.).

$$Molding shrinkage rate ( \% ) = ( ( D - d ) / D ) \times 100$$

TABLE 1

| | MB1 | MB2 | MB3 | MB5 | MB9 | MB13 | MB14 | MB24 | MB25 | MB28 | MB29 | MB30 |
|---|---|---|---|---|---|---|---|---|---|---|---|---|
| Epoxy | 100 | 100 | 100 | 100 | 100 | | | 100 | 100 | | | |
| resin 1 | | | | | | | | | | | | |
| Epoxy | | | | | | 100 | | | | | | |
| resin 2 | | | | | | | | | | | | |
| Epoxy | | | | | | | 100 | | | | | |
| resin 3 | | | | | | | | | | | | |
| Curing | | | | | | | | | | 100 | | |
| agent 1 | | | | | | | | | | | | |
| Curing | | | | | | | | | | | 100 | |
| agent 2 | | | | | | | | | | | | |
| Curing | | | | | | | | | | | | 100 |
| agent 3 | | | | | | | | | | | | |
| Inorganic | 817.1 | 891.4 | 965.7 | 817.1 | 817.1 | 817.1 | 817.1 | 817.1 | 742.9 | 742.9 | 742.9 | 742.9 |
| particle 1 | | | | | | | | | | | | |
| Inorganic | 238.3 | 260.0 | 281.7 | 238.3 | 238.3 | 238.3 | 238.3 | 238.3 | 216.7 | 216.7 | 216.7 | 216.7 |
| particle 2 | | | | | | | | | | | | |
| Coupling | 5.7 | 6.2 | 6.8 | 5.7 | 5.7 | 5.7 | 5.7 | 5.7 | 5.2 | 5.2 | 5.2 | 5.2 |
| agent | | | | | | | | | | | | |
| Silicone | 10 | 20 | 30 | | | 10 | 10 | | | | | |
| compound 1 | | | | | | | | | | | | |
| Silicone | | | | 10 | | | | | | | | |
| compound 2 | | | | | | | | | | | | |
| Silicone | | | | | 10 | | | | | | | |
| compound 3 | | | | | | | | | | | | |
| Silicone | | | | | | | | 10 | | | | |
| compound 4 | | | | | | | | | | | | |
| Inorganic | 78 | 78 | 78 | 78 | 78 | 78 | 78 | 78 | 78 | 76.5 | 76.5 | 76.5 |
| particle | | | | | | | | | | | | |
| (Volume %) | | | | | | | | | | | | |
| Residue | 2 | 3.6 | 10 | 2.5 | 1.5 | 3 | 2 | 25 | 60 | 1 | 2 | 1 |
| rate | | | | | | | | | | | | |
| (Mass %) | | | | | | | | | | | | |

TABLE 2

| | | | | | | | | | | | | Comparative | |
|---|---|---|---|---|---|---|---|---|---|---|---|---|---|
| | Example | | | | | | | | | | | Example | |
| | 1 | 2 | 3 | 4 | 5 | 6 | 7 | 8 | 9 | 10 | 11 | 1 | 2 |
| Epoxy | 43 | 46.2 | 49.4 | | | 43 | 43 | 33 | 33 | 21.7 | 4.8 | 39.7 | 43 |
| resin 1 | | | | | | | | | | | | | |
| Epoxy | | | | 40.3 | | | | | | | | | |
| resin 2 | | | | | | | | | | | | | |
| Epoxy | | | | | 38 | | | | | | | | |
| resin 3 | | | | | | | | | | | | | |
| MB-1 | 502.8 | | | | | | | | | 662 | 788.9 | | |
| MB-2 | | 553.5 | | | | | | | | | | | |
| MB-3 | | | 604.3 | | | | | | | | | | |
| MB-13 | | | | 522.6 | | | | | | | | | |
| MB-14 | | | | | 539.6 | | | | | | | | |
| MB-5 | | | | | | 502.8 | | | | | | | |
| MB-9 | | | | | | | 502.8 | | | | | | |
| MB-25 | | | | | | | | 502.8 | 502.8 | | | 452 | |
| MB-24 | | | | | | | | | | | | | 502.8 |
| MB-28 | 505.9 | 505.9 | 505.9 | | | 505.9 | 505.9 | 505.9 | 505.9 | 505.9 | 505.9 | 505.9 | 505.9 |
| MB-29 | | | | | 369.3 | | | | | | | | |
| MB-30 | | | | 428.5 | | | | | | | | | |
| Silicone | | | | | | | | 10 | | | | | |
| compound 1 | | | | | | | | | | | | | |
| Silicone | | | | | | | | | 10 | | | | |
| compound 2 | | | | | | | | | | | | | |
| Curing | 2.5 | 2.5 | 2.5 | 2.5 | 2.5 | 2.5 | 2.5 | 2.5 | 2.5 | 2.5 | 2.5 | 2.5 | 2.5 |
| accelerator | | | | | | | | | | | | | |
| Coupling | 5 | 5 | 5 | 5 | 5 | 5 | 5 | 5 | 5 | 5 | 5 | 5 | 5 |
| agent | | | | | | | | | | | | | |
| Release | 1 | 1 | 1 | 1 | 1 | 1 | 1 | 1 | 1 | 1 | 1 | 1 | 1 |
| agent | | | | | | | | | | | | | |
| Coloring | 3 | 3 | 3 | 3 | 3 | 3 | 3 | 3 | 3 | 3 | 3 | 3 | 3 |
| agent | | | | | | | | | | | | | |
| Total | 1063.2 | 1117.1 | 1171.1 | 1002.9 | 958.4 | 1063.2 | 1063.2 | 1063.2 | 1063.2 | 1201.1 | 1311.1 | 1009.1 | 1063.2 |
| Inorganic | 70 | 70 | 70 | 70 | 70 | 70 | 70 | 70 | 70 | 73 | 75 | 70 | 70 |
| particle | | | | | | | | | | | | | |
| (Volume %) | | | | | | | | | | | | | |
| SF | 130 | 130 | 110 | 110 | 110 | 120 | 130 | 135 | 135 | 100 | 80 | 150 | 120 |
| GT | 60 | 55 | 65 | 45 | 45 | 60 | 58 | 60 | 60 | 55 | 50 | 70 | 60 |
| Storage | 16 | 15 | 14.5 | 17 | 17 | 16.5 | 16 | 16.5 | 17 | 18.5 | 19 | 17.5 | 17 |
| modulus | | | | | | | | | | | | | |
| (GPa) | | | | | | | | | | | | | |
| Residue | 5 | 8 | 10 | 10 | 10 | 5 | 5 | 8 | 8 | 10 | 10 | 60 | 40 |
| rate | | | | | | | | | | | | | |
| (Mass %) | | | | | | | | | | | | | |
| Tg (° C.) | 110 | 110 | 110 | — | — | — | 125 | — | | — | — | 125 | — |
| Molding | 0.37 | 0.34 | 0.33 | — | — | — | 0.4 | — | | — | — | 0.4 | — |
| shrinkage | | | | | | | | | | | | | |
| rate (%) | | | | | | | | | | | | | |

The details of the materials listed in Table 1 and Table 2 are as follows.
Epoxy resin 1: NC-3000 (trade name, Nippon Kayaku Co., Ltd., aralkyl type epoxy resin with epoxy equivalent of 265 g/eq to 285 g/eq, softening point of 53° C. to 63° C.)
Epoxy resin 2: EPPN-501HY (trade name, Nippon Kayaku Co., Ltd., triphenylmethane type epoxy resin with epoxy equivalent of 163 g/eq to 175 g/eq, softening point of 57° C. to 63° C.)
Epoxy resin 3: N-500P (trade name, DIC Corporation, cresol novolac type epoxy resin with epoxy equivalent of 190 g/eq to 210 g/eq, softening point of 65° C. to 70° C.)
Curing agent 1: MEHC-7851SS (trade name, Meiwa Kasei Co., Ltd., biphenylene aralkyl type phenol resin with hydroxyl equivalent of 205 g/eq, softening point of 60° C. to 70° C.)
Curing agent 2: HP-850N (trade name, Resonac Corporation, phenol novolac resin with hydroxyl equivalent of 103 g/eq, softening point of 81° C. to 85° C.)
Curing agent 3: MEH7500-3S (trade name, Meiwa Kasei Co., Ltd., triphenylmethane type phenol resin with hydroxyl equivalent of 103 g/eq, softening point of 50° C. to 60° C.)
Inorganic particle 1: Dispersion of spherical silica particles with maximum particle diameter of 5 μm or less, volume average particle diameter of 1.5 μm, specific surface area of 3.0 m²/g to 4.0 m²/g by BET method (dispersion medium:methyl isobutyl ketone, content ratio of inorganic particles:70 mass %)
Inorganic particle 2: Dispersion of spherical silica particles with maximum particle diameter of 5 μm or less, volume average particle diameter of 0.3 μm, specific surface area of 9.0 m²/g to 11.0 m²/g by BET method (dispersion medium:methyl isobutyl ketone, content ratio of inorganic particles:60 mass %)
Silicone compound 1: SIM-768E (trade name, Momentive Performance Materials Inc., silicone compound containing polyoxyalkylene structure and epoxy group in side chain, epoxy equivalent 7300 g/eq, viscosity 3000 mPa·s)
Silicone compound 2: BY-16-876 (trade name, Dow Toray Co., Ltd., silicone compound containing polyoxyalkylene structure and epoxy group in side chain, epoxy equivalent 2200 g/eq to 3400 g/eq, viscosity 2500 mPa·s)
Silicone compound 3: KF-1005 (trade name, Shin-Etsu Chemical Co., Ltd., silicone compound containing polyoxyalkylene structure and aralkyl group in side chain, epoxy equivalent 250 g/eq, viscosity 2500 mm²/s)
Silicone compound 4: X-22-163C (trade name, Shin-Etsu Chemical Co., Ltd., both-terminal epoxy-modified silicone compound, epoxy equivalent 2700 g/eq, viscosity 120 mm²/s)
Coupling agent: KBM-573 (trade name, Shin-Etsu Chemical Co., Ltd., N-phenyl-3-aminopropyltrimethoxysilane)
Curing accelerator: Phosphorus-based curing accelerator
Release agent: Montan acid ester
Coloring agent: Carbon black

As shown in Table 2, the resin compositions of the examples using silicone compounds containing oxyalkylene structures as raw materials had smaller residue rates of resin composition compared to the resin composition of Comparative Example 1, which did not use a silicone compound, or Comparative Example 2, which used a silicone compound without an oxyalkylene structure as a raw material. From these results, it is understood that the resin composition of the present disclosure exhibits excellent dispersibility of inorganic particles even when the particle size of the inorganic particles is small.

The disclosure of Japanese Patent Application No. 2022-196516 is incorporated in its entirety into this specification by reference.

All literature, patent applications, and technical standards described in this specification are incorporated into this specification by reference to the same extent as if each individual literature, patent application, and technical standard were specifically and individually indicated to be incorporated by reference.

1. A resin composition, containing a resin component, inorganic particles, and a compound containing an oxyalkylene structure, wherein a maximum particle diameter of the inorganic particles is 5 μm or less.

2. The resin composition according to claim 1, wherein the resin component contains an epoxy resin.

3. The resin composition according to claim 1, wherein a compound containing the oxyalkylene structure contains a silicone compound.

4. The resin composition according to claim 1, for use as a sealing material for an electronic component device.

5. An electronic component device, comprising:
an element sealed with a resin composition according to claim 1.
